(19) United States
(12) Patent Application Publication
(10) Pub. No.: US 2025/0233107 A1
(43) Pub. Date: Jul. 17, 2025

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Ryotaro TSURUOKA, Matsumoto-city (JP)

(73) Assignee: FUJI ELECTRIC CO., LTD., Kawasaki-shi (JP)

(21) Appl. No.: 19/093,921

(22) Filed: Mar. 28, 2025

Related U.S. Application Data
(63) Continuation of application No. PCT/JP2024/008876, filed on Mar. 7, 2024.

(30) Foreign Application Priority Data
Apr. 19, 2023 (JP) 2023-068374

(51) Int. Cl. H01L 23/00; H01L 23/498

(52) U.S. Cl. CPC H01L 24/92; H01L 24/32; H01L 24/40; H01L 24/73; H01L 24/83; H01L 24/84; H01L 23/49861; H01L 2224/32227; H01L 2224/40229; H01L 2224/73263; H01L 2224/83002; H01L 2224/83203; H01L 2224/8384; H01L 2224/84002; H01L 2224/84203; H01L 2224/8484; H01L 2224/9221

(57) ABSTRACT

A method of manufacturing the semiconductor device includes: preparing a lead member including a bonding part and a beam part continuously connected to the bonding part; preparing a pressing jig provided with an opening; placing the bonding part, with sintering material interposed, on a semiconductor chip provided on a conductive layer of an insulated circuit substrate, the insulated circuit substrate including an insulating plate and the conductive layer provided on the insulating plate; placing the pressing jig on the bonding part, the sintering material, the semiconductor chip, and the conductive layer so that the opening overlaps with the beam part; and applying pressure and heat to the bonding part, the sintering material, the semiconductor chip, and the conductive layer by the pressing jig.

### CROSS-REFERENCE TO RELATED APPLICATION

This application is a Continuation of PCT Application No. PCT/JP2024/008876, filed on Mar. 7, 2024, and claims the priority of Japanese Patent Application No. 2023-068374, filed on Apr. 19, 2023, the content of which are incorporated herein by reference.

### TECHNICAL FIELD

The present invention relates to semiconductor devices and methods of manufacturing the same.

### BACKGROUND ART

WO2020/075549A1 discloses a semiconductor device including a semiconductor element having an element obverse face and an element reverse face formed with an obverse-face electrode and a reverse-face electrode on the element obverse face and the element reverse face, respectively, a first conductor opposing the element reverse face and conductively bonded to the reverse-face electrode, a second conductor spaced apart from the first conductor and electrically connected to the obverse-face electrode, and a lead member having a lead obverse face facing in the same direction as the element obverse face, the lead member connecting the obverse-face electrode and the second conductor to each other, wherein the lead member includes a protrusion protruding in the thickness direction from the lead obverse face, and is bonded to the obverse-face electrode via a lead bonding layer, and the protrusion overlaps with the obverse-face electrode as viewed in the thickness direction, so as to suppress deformation of the connecting member caused by pressure applied during sintering processing.

JP2018-116995A discloses a method of manufacturing a power module capable of facilitating the manufacture by bonding a semiconductor element and a lead member together so as to avoid a cause of a warp while preventing a bonding fault or damage to the semiconductor element, the method stacking a power-module substrate, the semiconductor element, and the lead member in a state in which a silver-paste layer is interposed between a circuit layer of the power-module substrate and the semiconductor element and between the semiconductor element and the lead member, and executing heating while applying a pressure to these members in the stacking direction to sinter the silver-paste layer so as to bond the circuit layer and the semiconductor element together and also the semiconductor element and the lead member together.

JP2018-006492A discloses a semiconductor device including a substrate, a semiconductor chip provided on the substrate and having a front-surface electrode and a rear-surface electrode provided on the opposite side of the front-surface electrode, a lead member provided to be opposed to the front-surface electrode of the semiconductor chip, a first bonding part provided between the substrate and the rear-surface electrode of the semiconductor chip, and a second bonding part provided between the front-surface electrode of the semiconductor chip and the lead member, wherein the lead member includes an electrode part connected to the front-surface electrode via the second bonding part, a bridge part connecting the respective electrodes, and a resin layer provided on the top surface of the electrode part, and the resin layer is provided on the bottom surface of the bridge part and a part of the bottom surface of the electrode part not bonded to the front-surface electrode, so as to apply a uniform load to the entire surface of the semiconductor chip and simultaneously press and bond the bonding parts on the front and rear surfaces of the semiconductor chip.

### SUMMARY OF THE INVENTION

### Technical Problem

Study in conventional semiconductor devices has been promoted that have a configuration capable of bonding a semiconductor chip provided on an insulated circuit substrate and a lead member together by use of a bonding layer including sintering material.

However, such a conventional semiconductor device would lead to an unbonded state between the lead member and the bonding layer because of deformation of the lead member upon pressure application and heat application for sintering the bonding layer.

In view of the foregoing problems, the present invention provides a semiconductor device and a method of manufacturing the same capable of preventing deformation of a lead member upon pressure application when bonding a semiconductor chip and the lead member together by use of a bonding layer including sintering material so as to avoid a cause of an unbonded state between the semiconductor chip and the bonding layer.

### Solution to Problem

An aspect of the present invention inheres in a semiconductor device including: an insulated circuit substrate including an insulating plate and a conductive layer provided on the insulating plate; a semiconductor chip provided on the conductive layer; a bonding layer including sintering material provided on the semiconductor chip; and a lead member including a bonding part provided on the bonding layer and a beam part continuously connected to the bonding part, wherein the bonding layer includes a middle region located immediately under the bonding part, and a circumferential region located on an outer side of the middle region, and the circumferential region has lower sintered density at a part located immediately under the lead member than at a part other than the part located immediately under the lead member.

Another aspect of the present invention inheres in a method of manufacturing a semiconductor device, including: preparing a lead member including a bonding part and a beam part continuously connected to the bonding part; preparing a pressing jig provided with an opening; placing the bonding part, with sintering material interposed, on a semiconductor chip provided on a conductive layer of an insulated circuit substrate, the insulated circuit substrate including an insulating plate and the conductive layer provided on the insulating plate; placing the pressing jig on the bonding part, the sintering material, the semiconductor chip, and the conductive layer so that the opening overlaps with the beam part; and applying pressure and heat to the bonding part, the sintering material, the semiconductor chip, and the conductive layer by the pressing jig.

### BRIEF DESCRIPTION OF THE DRAWINGS

FIG. 1 is a cross-sectional view illustrating a semiconductor device according to a first embodiment;

FIG. 2 is a cross-sectional view illustrating a part of the semiconductor device according to the first embodiment;

FIG. 3 is a plan view illustrating a part of the semiconductor device according to the first embodiment;

FIG. 4 is a plan view illustrating a sintering material in the semiconductor device according to the first embodiment;

FIG. 5 is a plan view illustrating another sintering material in the semiconductor device according to the first embodiment;

FIG. 6 is a cross-sectional process view illustrating a method of manufacturing the semiconductor device according to the first embodiment;

FIG. 7 is a cross-sectional process view continued from FIG. 6, illustrating the method of manufacturing the semiconductor device according to the first embodiment;

FIG. 8 is a cross-sectional process view continued from FIG. 7, illustrating the method of manufacturing the semiconductor device according to the first embodiment;

FIG. 9 is a cross-sectional process view continued from FIG. 8, illustrating the method of manufacturing the semiconductor device according to the first embodiment;

FIG. 10 is a plan view corresponding to FIG. 9;

FIG. 11 is a cross-sectional process view illustrating a method of manufacturing a semiconductor device of a first comparative example;

FIG. 12 is a cross-sectional process view illustrating a method of manufacturing a semiconductor device of a second comparative example;

FIG. 13 is a plan process view illustrating a method of manufacturing a semiconductor device according to a second embodiment;

FIG. 14 is a plan process view illustrating a method of manufacturing a semiconductor device according to a third embodiment;

FIG. 15 is a cross-sectional process view illustrating a method of manufacturing a semiconductor device according to a fourth embodiment;

FIG. 16 is a cross-sectional process view illustrating a method of manufacturing a semiconductor device according to a fifth embodiment;

FIG. 17 is a cross-sectional process view illustrating a method of manufacturing a semiconductor device according to a sixth embodiment;

FIG. 18 is a cross-sectional process view illustrating a method of manufacturing a semiconductor device according to a seventh embodiment; and

FIG. 19 is a cross-sectional process view illustrating a method of manufacturing a semiconductor device according to an eighth embodiment.

### DETAILED DESCRIPTION

With reference to the drawings, first to eighth embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to eighth embodiments described below merely illustrate schematically devices and methods for specifying and giving shapes to the technical idea of the present disclosure, and the span of the technical idea is not limited to materials, shapes, structures, and relative positions of elements described herein.

In the specification, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

### First Embodiment

### <Configuration of Semiconductor Device>

A semiconductor device (a semiconductor module) according to a first embodiment includes an insulated circuit substrate 1, a semiconductor chip 3 provided on the insulated circuit substrate 1, and a lead member (also referred to below as a “lead frame” or a “terminal”, for example) provided on the semiconductor chip 3 and the insulated circuit substrate 1.

The insulated circuit substrate 1 includes an insulating plate 11, conductive layers (metal pattern layers) 12a and 12b provided separately from each other on one of the main surfaces (on the top surface) of the insulating plate 11, and a conductive layer (a metal pattern layer) 13 provided on the other main surface (on the bottom surface) of the insulating plate 11. The semiconductor chip 3 is bonded onto the conductive layer 12a of the insulated circuit substrate 1 with a bonding layer 2a interposed. One end of the lead member 4 is bonded onto the semiconductor chip 3 with a bonding layer 2b interposed. The other end of the lead member 4 is bonded onto the conductive layer 12b of the insulated circuit substrate 1 with a bonding layer 2c interposed.

The insulated circuit substrate 1 may be a direct copper bonded (DCB) substrate or an active metal brazed (AMB) substrate, for example. The insulating plate 11 is a ceramic substrate formed from any of aluminum oxide (Al₂O₃), aluminum nitride (AlN), or silicon nitride (Si₃N₄), or a resin-insulating substrate including polymer material, for example. The conductive layers 12a and 12b and the conductive layer 13 are each a conductor foil of metal such as copper (Cu) and aluminum (Al), for example.

The bonding layers 2a to 2c are each a bonding layer including porous sintering material (also referred to below as a “sintered bonding layer”) having voids (pores) between metallic grains included in the sintering material. Examples of metallic grains included in the sintering material include gold (Au), silver (Ag), and copper (Cu) having a grain diameter of several nanometers or greater and several micrometers or smaller, for example. The respective bonding layers 2a to 2c have thermal conductivity in a range of 150 W/mK or higher and 400 W/mK or lower, a coefficient of linear thermal expansion of about 19×10⁻¹⁶/° C., and a melting point of about 960° C., for example. The bonding layers 2a to 2c thus exhibit stable strength at a usage temperature of the semiconductor device (in a range of 150° C. or higher and 170° C. or lower, for example). The sintering material before the bonding layers 2a to 2c are sintered is in a state in which fine metallic grains coated with an organic substance are mixed in an organic solvent. Applying pressure and heat to the sintering material in a state of being provided between targets to be bonded leads the organic solvent and the coating organic substance to be evaporated and leads the fine metallic grains exposed to be fused and sintered, so as to provide the respective bonding layers 2a to 2c.

The respective bonding layers 2a to 2c may include either the same material or different materials. The respective bonding layers 2a to 2c may either have the same thickness or different thicknesses. The respective bonding layers 2a to 2c may be formed either simultaneously or independently of each other. The bonding layers 2a and 2b preferably have the same thickness when formed simultaneously, for example.

The semiconductor chip 3 is provided such that the bottom surface is opposed to the top surface of the conductive layer 12a. The semiconductor chip 3 as used herein can be an insulated gate bipolar transistor (IGBT), a field-effect transistor (FET), a static induction (SI) thyristor, a gate turn-off (GTO) thyristor, or a freewheeling diode (FWD), for example. The semiconductor chip 3 may be implemented by a silicon (Si) substrate, or a compound semiconductor substrate using a wide-bandgap semiconductor including silicon carbide (SiC), gallium nitride (GaN), or gallium oxide (Ga₂O₃), for example. The conductive layer 12a is bonded onto a bottom-surface electrode of the semiconductor chip 3 with the bonding layer 2a interposed. The lead member 4 is bonded onto a top-surface electrode of the semiconductor chip 3 with the bonding layer 2b interposed. When the semiconductor chip 3 is an IGBT, for example, the bottom-surface electrode is a collector electrode, and the top-surface electrode is an emitter electrode.

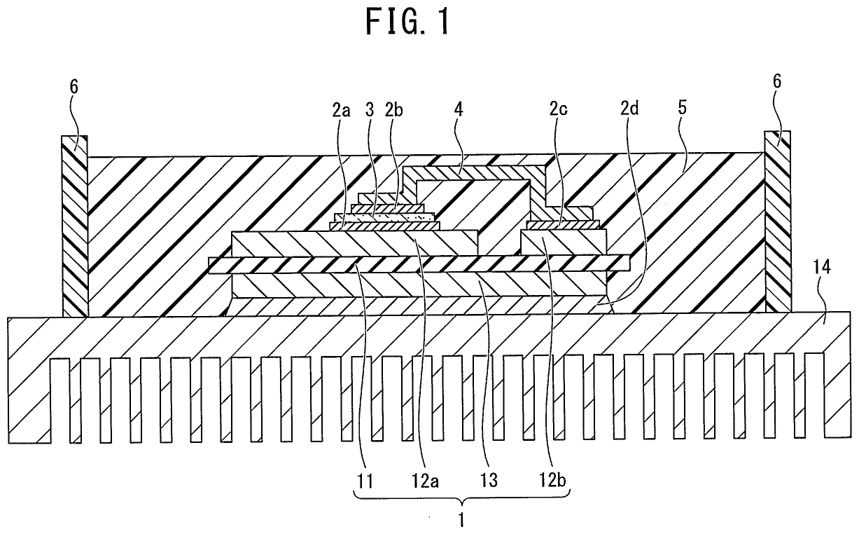

While FIG. 1 illustrates the case of including the single semiconductor chip 3, the number of the semiconductor chips provided can be determined as appropriate depending on a current capacity of the semiconductor module, for example, and the semiconductor module may include two or more semiconductor chips. While FIG. 1 illustrates the case of including the single lead member 4, the number of the lead members provided can be determined as appropriate depending on the number of the semiconductor chips, and the semiconductor module may include two or more lead members.

The semiconductor device according to the first embodiment further includes sealing resin 5 for sealing the insulated circuit substrate 1, the semiconductor chip 3, the lead member 4, the respective bonding layers 2a to 2c, and the like, and includes a case 6 provided at the circumference of the sealing resin 5.

The sealing resin 5 includes epoxy resin, phenol resin, and maleimide resin as a main agent, for example. The sealing resin 5 may further include inorganic filler in addition to the main agent. The inorganic filler may be a metal oxide or a metal nitride including any of fused silica, silica (silicon oxide), alumina, aluminum hydroxide, titania, zirconia, aluminum nitride, talc, clay, mica, and glass fiber, or two or more of these materials mixed together.

The case 6 is formed from resin such as polyphenylene sulfide (PPS) and polybutylene terephthalate (PBT), for example. The case 6 may be provided with external terminals (not illustrated) that can be connected to an external circuit. The external terminals (not illustrated) may be connected to the semiconductor chip 3 or the conductive layers 12a and 12b via bonding wires (not illustrated), or may be connected to the semiconductor chip 3 or the conductive layers 12a and 12b with a bonding layer (not illustrated) including solder or sintering material interposed.

The semiconductor device according to the first embodiment further includes a cooling device (a heat-releasing fin) 14 provided under the insulated circuit substrate 1. The cooling device 14 is bonded to the conductive layer 13 of the insulated circuit substrate 1 with a bonding layer 2d interposed. The bonding layer 2d includes sintering material, solder, or thermal interface material (TIM), for example. TIM as used herein can be thermal-conductive material (a thermal compound), such as thermal-conductive grease, an elastomer sheet, room temperature vulcanization (RTV) rubber, gel, phase-change material, and silver wax. The cooling device 14 is formed from metal such as copper (Cu) and aluminum (Al). The cooling device 14 may have either a structure provided with fins on a top plate or a flat-shaped structure not provided with any fins under the top plate.

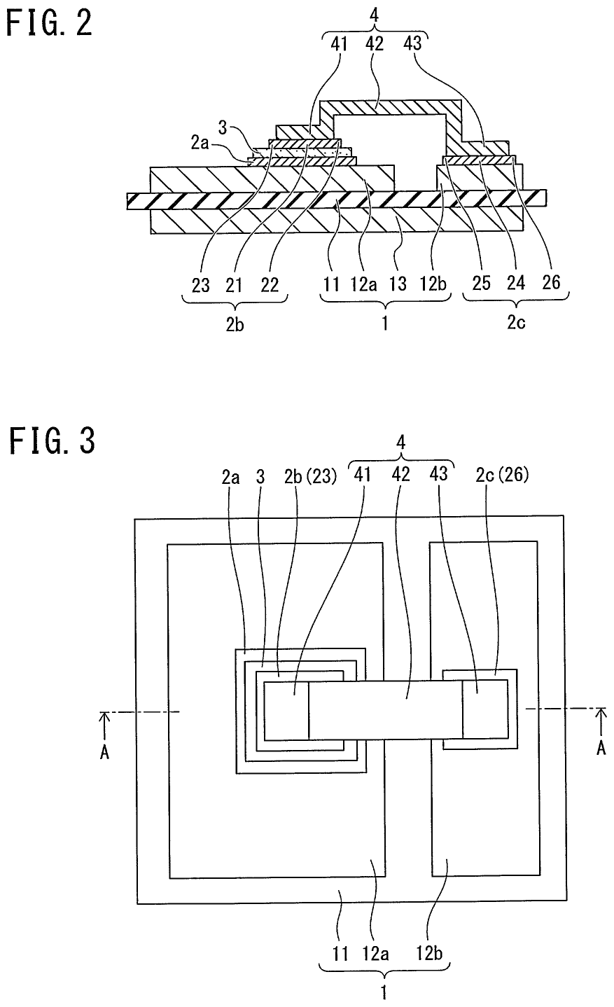

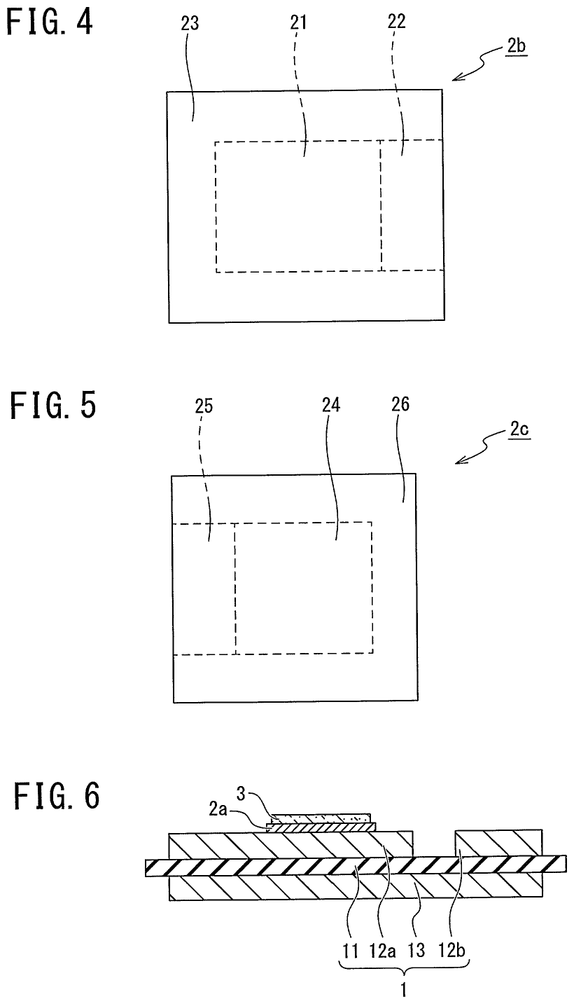

FIG. 2 is a cross-sectional view illustrating the insulated circuit substrate 1, the semiconductor chip 3, the lead member 4, and the respective bonding layers 2a to 2c party extracting from the illustration of FIG. 1. FIG. 3 is a plan view corresponding to FIG. 2. FIG. 2 corresponds to the cross section as viewed from direction A-A in FIG. 3. FIG. 4 is a plan view illustrating the bonding layer 2b. FIG. 5 is a plan view illustrating the bonding layer 2c.

As illustrated in FIG. 2 and FIG. 3, the lead member 4 includes a bonding part 41, a beam part 42 continuously extending from the bonding part 41, and a bonding part 43 provided to be continuously connected with the beam part 42. The bonding part 41 is a part bonded to the top surface of the semiconductor chip 3 with the bonding layer 2b interposed. The bonding part 41 has a substantially rectangular planar pattern having a bottom surface parallel to the top surface of the semiconductor chip 3. The bonding part 43 is a part bonded to the top surface of the conductive layer 12b of the insulated circuit substrate 1 with the bonding layer 2c interposed. The bonding part 43 has a substantially rectangular planar pattern having a bottom surface parallel to the top surface of the conductive layer 12b. The horizontal level (the height in the vertical direction) of the bonding part 41 is higher than the horizontal level (the height in the vertical direction) of the bonding part 43 by the thickness of the bonding layer 2a and the semiconductor chip 3.

The beam part 42 includes a first standing part extending upward in the vertical direction from the top surface of the bonding part 41, a second standing part extending upward in the vertical direction from the top surface of the bonding part 43, and a middle part bent into an L-like shape from the respective upper edges of the first standing part and the second standing part so as to extend in the horizontal direction. A length of the first standing part in the vertical direction is shorter than that of the second standing part in the vertical direction so that the middle part extends horizontally.

As illustrated in FIG. 3, the insulating plate 11 and the conductive layers 12a and 12b of the insulated circuit substrate 1 each have a substantially rectangular planar pattern. The arranged positions and the number of the conductive layers 12a and 12b are not limited to the case as illustrated. The bonding layer 2a has a substantially rectangular planar pattern. The semiconductor chip 3 has a substantially rectangular planar pattern. The semiconductor chip 3 has a smaller size than the bonding layer 2a in the planar pattern. The outer circumference of the semiconductor chip 3 is located on the inside of the outer circumference of the bonding layer 2a.

As illustrated in FIG. 2 to FIG. 4, the bonding layer 2b has a substantially rectangular planar pattern. The bonding layer 2b has a smaller size than the semiconductor chip 3 in the planar pattern, and has a larger size than the bonding part 41 in the planar pattern. The outer circumference of the bonding layer 2b is located on the inside of the outer circumference of the semiconductor chip 3, and is located on the outside of the outer circumference of the bonding part 41.

The bonding layer 2b includes a middle region 21, and circumferential regions 22 and 23 located along the circumference of the middle region 21. The middle region 21 is located immediately under the bonding part 41 of the lead member 4 so as to be bonded to the bonding part 41.

The circumferential regions 22 and 23, which are located on the outside of the middle region 21 in the planar view, are not bonded to the bonding part 41. The circumferential region 22 of the circumferential regions 22 and 23 includes a part located immediately under (below) the beam part 42 of the lead member 4. The circumferential region 22 has a substantially rectangular planar pattern and is located next to one side of the rectangle of the planar pattern of the middle region 21. The circumferential region 23 of the circumferential regions 22 and 23 is a part excluding the circumferential region 22 located immediately under (below) the beam part 42 of the lead member 4. The circumferential region 23 has a substantially C-shaped planar pattern surrounding the middle region 21 and the circumferential region 22. The circumferential region 23 includes a part opposite to the circumferential region 22 about the middle region 21 in the extending direction of the beam part 42 of the lead member 4.

The middle region 21 and the circumferential region 23 are pressed upon the bonding of the bonding layer 2b, while the circumferential region 22 is not pressed upon the bonding of the bonding layer 2b. The middle region 21 and the circumferential region 23 thus have higher sintered density than the circumferential region 22. The term “sintered density” as used in the present description refers to density of metallic grains composing sintering material, which is a ratio of a volume of the bonding layer excluding open pores and closed pores to the entire volume of the bonding layer including the open pores and the closed pores. The porosity between metallic grains composing the sintering material included in the middle region 21 and the circumferential region 23 is lower than the porosity between metallic grains composing the sintering material included in the circumferential region 22.

As illustrated in FIG. 2, FIG. 3, and FIG. 5, the bonding layer 2c has a substantially rectangular planar pattern. The bonding layer 2c has a larger size than the bonding part 43 in the planar pattern. The outer circumference of the bonding layer 2c is located on the outside of the bonding part 43.

The bonding layer 2c includes a middle region 24, and circumferential regions 25 and 26 located along the circumference of the middle region 24. The middle region 24 is located immediately under the bonding part 43 of the lead member 4 so as to be bonded to the bonding part 43.

The circumferential regions 25 and 26, which are located on the outside of the middle region 24 in the planar view, are not bonded to the bonding part 43. The circumferential region 25 of the circumferential regions 25 and 26 includes a part located immediately under (below) the beam part 42 of the lead member 4. The circumferential region 25 has a substantially rectangular planar pattern and is located next to one side of the rectangle of the planar pattern of the middle region 24. The circumferential region 26 of the circumferential regions 25 and 26 is a part excluding the circumferential region 25 located immediately under (below) the beam part 42 of the lead member 4. The circumferential region 26 has a substantially C-shaped planar pattern surrounding the middle region 24 and the circumferential region 25.

The middle region 24 and the circumferential region 26 are pressed upon the bonding of the bonding layer 2c, while the circumferential region 25 is not pressed upon the bonding of the bonding layer 2c. The middle region 24 and the circumferential region 26 thus have higher sintered density than the circumferential region 25. The porosity between metallic grains composing the sintering material included in the middle region 24 and the circumferential region 26 is lower than the porosity between metallic grains composing the sintering material included in the circumferential region 25.

The configuration of the semiconductor device according to the first embodiment as described above, in which the semiconductor chip 3 is bonded to the lead member 4 via the bonding layer 2b including the sintering material, can achieve higher heat resistance, higher heat-releasing performance, and higher reliability than a case of being bonded via solder.

### <Method of Manufacturing Semiconductor Device>

An example of a method of manufacturing (assembling) the semiconductor device according to the first embodiment is described below.

First, the insulated circuit substrate 1 provided with the conductive layers 12a and 12b on the top surface of the insulating plate 11 is prepared (refer to FIG. 6). The semiconductor chip 3 is then disposed on the conductive layer 12a of the insulated circuit substrate 1 via sintering material (refer to FIG. 6). The sintering material may be either a sheet-state sintering material (a sintering sheet) or paste-state sintering material (sintering paste). The sintering material may be disposed on the conductive layer 12a by paste printing or by dispensing, for example. Alternatively, the sintering material may be attached to the bottom surface of the semiconductor chip 3 so as to be disposed on the conductive layer 12a.

Next, the insulated circuit substrate 1, the sintering material, and the semiconductor chip 3 are pressed in the stacked direction and heated by use of a metal die (not illustrated) arranged on the bottom surface side of the insulated circuit substrate 1 and a metal die (not illustrated) arranged on the top surface side of the semiconductor chip 3 so as to cause a reaction to sinter the sintering material. A pressing force is set in a range of about 1 MPa or greater and 60 MPa or lower, a heating temperature is set in a range of about 150° C. or higher and 350° C. or lower, and a heating time is set in a range of about 1 minute or longer and 5 minutes or shorter, for example. This step leads the semiconductor chip 3 to be bonded onto the conductive layer 12a of the insulated circuit substrate 1 with the bonding layer 2a interposed, as illustrated in FIG. 6.

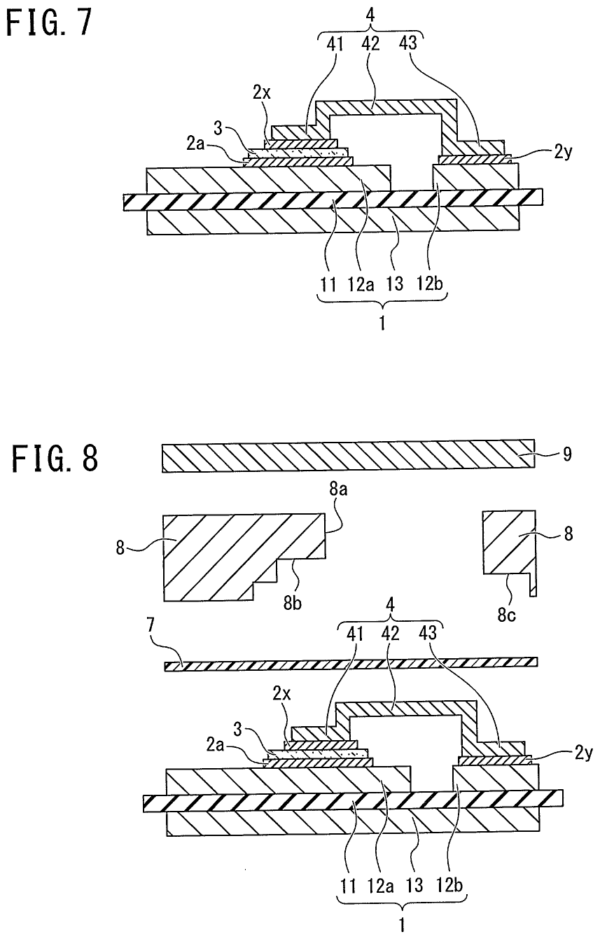

Next, as illustrated in FIG. 7, the lead member 4 is disposed on the respective top surfaces of the semiconductor chip 3 and the conductive layer 12b with the sintering materials 2x and 2y interposed. The sintering materials 2x and 2y may be provided either such that a sheet-state sintering material (a sintering sheet) is disposed on the top surfaces of the semiconductor chip 3 and the conductive layer 12b or such that paste-state sintering material (sintering paste) is applied to the top surfaces of the semiconductor chip 3 and the conductive layer 12b. Alternatively, the sintering materials 2x and 2y may be attached to the bottom surface of the lead member 4 so as to be disposed on the top surfaces of the semiconductor chip 3 and the conductive layer 12b.

Next, as illustrated in FIG. 8, a protection sheet 7, a pressing jig 8, and a pressing plate 9 are prepared. The protection sheet 7 is formed from material with a thickness so as to be deformable by pressure. The material of the protection sheet 7 to be used is fluororesin such as polytetrafluoroethylene (PTFE) or polyimide resin, for example. A thickness of the protection sheet 7 is set in a range of about 0.1 millimeters or greater and 1.0 millimeters or less, for example, but is not limited to this range.

The pressing jig 8 is formed from metal such as stainless steel (SUS), for example. The pressing jig 8 is provided with an opening 8a. The pressing jig 8 is also provided with stepped parts 8b and 8c on the bottom surface side. The stepped parts 8b and 8c are formed to have a shape so as to be fitted to the stepped parts defined by the stacked layers of the insulated circuit substrate 1, the bonding layer 2a, the semiconductor chip 3, the sintering materials 2x and 2y, and the lead member 4.

The pressing plate 9 is formed from metal such as stainless steel (SUS), for example. The pressing plate 9 has a flat plate-like shape. The protection sheet 7 and the pressing plate 9 are not necessarily placed. A buffer member using a carbon sheet may be arranged between the protection sheet 7 and the pressing jig 8.

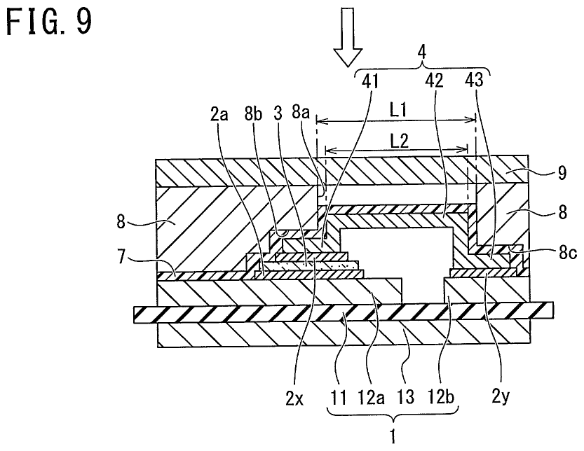

Next, as illustrated in FIG. 9, the pressing jig 8 is placed on the insulated circuit substrate 1, the bonding layer 2a, the semiconductor chip 3, the sintering materials 2x and 2y, and the lead member 4 with the protection sheet 7 interposed, and the pressing plate 9 is further placed on the pressing jig 8. The opening 8a of the pressing jig 8 overlaps with and houses the beam part 42 inside. In this state, the insulated circuit substrate 1, the bonding layer 2a, the semiconductor chip 3, the sintering materials 2x and 2y, and the lead member 4 are pressed in the stacked direction and heated by use of a metal die (not illustrated) arranged on the bottom surface side of the insulated circuit substrate 1 and a metal die (not illustrated) arranged on the top surface side of the pressing plate 9 so as to cause a reaction to sinter the sintering materials 2x and 2y. A pressing force is set in a range of about 1 MPa or higher and 60 MPa or smaller, a heating temperature is set in a range of about 150° C. or higher and 350° C. or lower, and a heating time is set in a range of about 1 minute or longer and 5 minutes or shorter, for example.

The arrow illustrated in FIG. 9 schematically indicates the pressure-applying state. The pressure applied by the pressing jig 8 selectively presses the conductive layers 12a and 12b of the insulated circuit substrate 1, the sintering materials 2x and 2y, the semiconductor chip 3, and the bonding parts 41 and 43 with the protection sheet 7 interposed. The beam part 42 of the lead member 4, which is housed in the opening 8a of the pressing jig 8, is not pressed by the pressing jig 8.

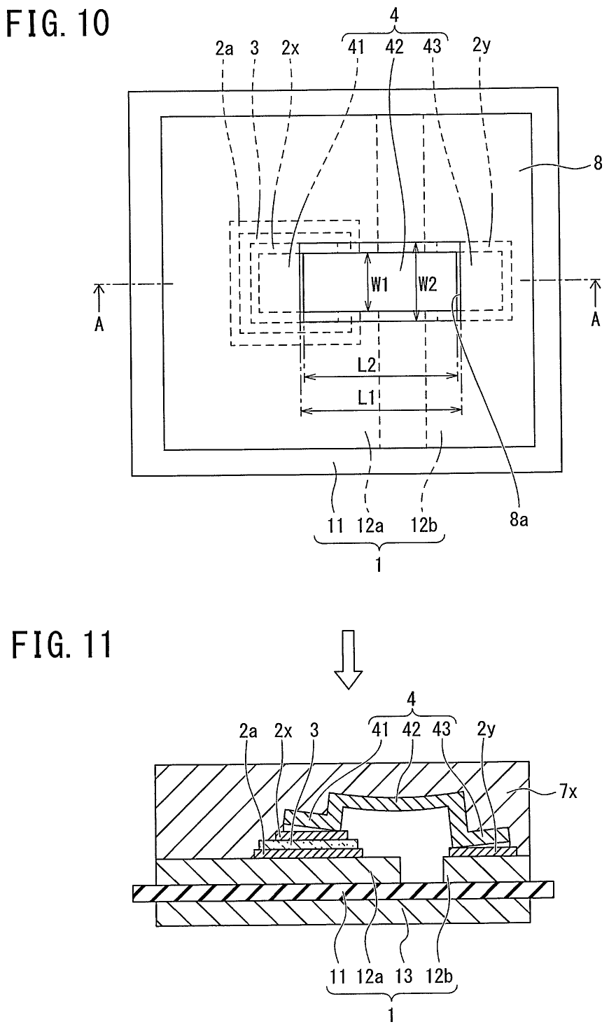

FIG. 10 is a plan view corresponding to FIG. 9, omitting the illustration of the protection sheet 7 and the pressing plate 9 while schematically indicating the members hidden under the pressing jig 8 by the broken lines. As illustrated in FIG. 10, the outer circumference of the pressing jig 8 substantially conforms to the respective outer circumferences of the conductive layers 12a and 12b. The outer circumference of the pressing jig 8 may be located either on the inside or on the outside of the respective outer circumferences of the conductive layers 12a and 12b instead. While the present embodiment is illustrated with the case in which the pressing jig 8 entirely presses the conductive layers 12a and 12b of the insulated circuit substrate 1 including the respective end parts, the pressing jig 8 does not necessarily press the end parts but may press the conductive layers 12a and 12b excluding the end parts.

The opening 8a of the pressing jig 8 overlaps with the beam part 42 of the lead member 4. The opening 8a has a larger size than the beam part 42 in the planar pattern. A width W2 of the opening 8a is wider than a width W1 of the beam part 42 in a direction perpendicular to the extending direction of the beam part 42 (in the short-side direction of the beam part 42). A length L1 of the opening 8a is longer than a length L2 of the beam part 42 in the extending direction of the beam part 42 (in the longitudinal direction of the beam part 42). The opening 8a has a substantially rectangular planar pattern, but the planar pattern is not limited to the rectangular shape, and may be a circular shape, for example.

This step sinters the sintering materials 2x and 2y to lead to the bonding layers 2b and 2c so that the semiconductor chip 3 and the bonding part 41 of the lead member 4 are bonded together via the bonding layer 2b, and the conductive layer 12b and the bonding part 43 of the lead member 4 are bonded together via the bonding layer 2c, as illustrated in FIG. 2 and FIG. 3. While the middle region 21 and the circumferential region 23 of the bonding layer 2b are pressed, the circumferential region 22 of the bonding layer 2b is not pressed. The middle region 21 and the circumferential region 23 thus have the higher sintered density than the circumferential region 22. Further, the middle region 21 and the circumferential region 23 have the lower porosity between metallic grains than the circumferential region 22. Similarly, the middle region 24 and the circumferential region 26 of the bonding layer 2c are pressed, but the circumferential region 25 of the bonding layer 2c is not pressed. The middle region 24 and the circumferential region 26 thus have the higher sintered density than the circumferential region 25. Further, the middle region 24 and the circumferential region 26 have the lower porosity between metallic grains than the circumferential region 25.

The region including the part of the sintering material 2x immediately under the beam part 42 and the part of the sintering material 2x exposed to the opening 8a illustrated in FIG. 10 corresponds to the circumferential region 22 of the bonding layer 2b not pressed. Further, the region including the part of the sintering material 2y immediately under the beam part 42 and the part of the sintering material 2y exposed to the opening 8a illustrated in FIG. 10 corresponds to the circumferential region 25 of the bonding layer 2c not pressed. The planar pattern of the circumferential region 22 of the bonding layer 2b illustrated in FIG. 4 and the planar pattern of the circumferential region 25 of the bonding layer 2c illustrated in FIG. 5 each correspond to the state in which the width W2 of the opening 8a illustrated in FIG. 10 substantially approximates to the width W1 of the beam part 42 so that the sintering materials 2x and 2y have substantially no part exposed to the opening 8a. The part of the sintering material 2x immediately under the beam part 42 thus substantially conforms to the circumferential region 22 of the bonding layer 2b, and the part of the sintering material 2y immediately under the beam part 42 substantially conforms to the circumferential region 25 of the bonding layer 2c. Subsequently, the protection sheet 7, the pressing jig 8, and the pressing plate 9 are removed from the stacked structure of the insulated circuit substrate 1, the bonding layers 2a to 2c, the semiconductor chip 3, and the lead member 4.

Next, the cooling device 14 is bonded on the bottom surface side of the insulated circuit substrate 1 with the bonding layer 2d interposed. Next, the case 6 is arranged on the cooling device 14 so as to surround the respective circumferences of the insulated circuit substrate 1, the semiconductor chip 3, the lead member 4, and the bonding layers 2a to 2d. Thereafter, the case 6 is filled inside with the sealing resin 5 so as to seal the insulated circuit substrate 1, the semiconductor chip 3, the lead member 4, and the bonding layers 2a to 2d. The semiconductor device according to the first embodiment illustrated in FIG. 1 is thus completed.

A method of manufacturing a semiconductor device of a first comparative example is described below. The method of manufacturing the semiconductor device of the first comparative example differs from the method of manufacturing the semiconductor device according to the first embodiment in applying a pressure to the entire lead member 4 by use of a metal die (not illustrated) with a buffer member 7x of a carbon sheet interposed, as illustrated in FIG. 11. The arrow illustrated in FIG. 11 schematically indicates the pressure-applying state. The method of manufacturing the semiconductor device of the first comparative example, which presses not only the bonding parts 41 and 43 but also the beam part 42 in the lead member 4, leads the beam part 42 to be deformed to thus lead the bonding parts 41 and 43 to be partly lifted up, which would cause an unbonded state between the bonding parts 41 and 43 and the sintering materials 2x and 2y.

In contrast, the method of manufacturing the semiconductor device according to the first embodiment executes the pressing process in the state in which the beam part 42 of the lead member 4 overlaps with and is exposed to the opening 8a of the pressing jig 8, so as not to apply the pressure to the beam part 42, as illustrated in FIG. 9 and FIG. 10. This can prevent the lead member 4 from being deformed, so as to avoid an unbonded state between the bonding parts 41 and 43 and the sintering materials 2x and 2y accordingly.

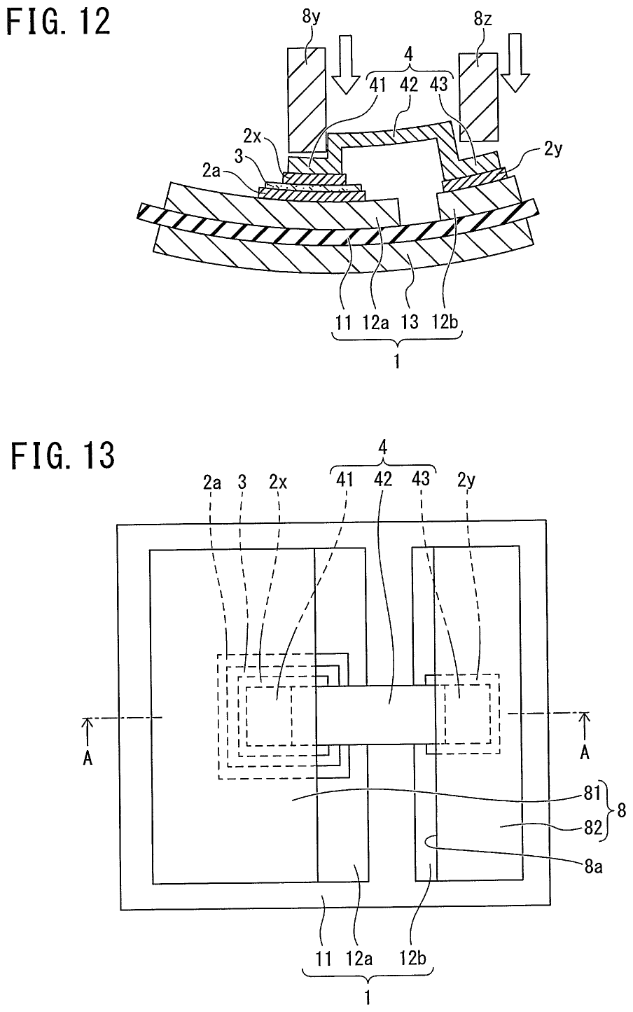

A method of manufacturing a semiconductor device of a second comparative example is described below. The method of manufacturing the semiconductor device of the second comparative example differs from the method of manufacturing the semiconductor device according to the first embodiment in that pressing jigs 8y and 8z press the bonding parts 41 and 43 of the lead member 4 independently of each other, as illustrated in FIG. 12. The arrow illustrated in FIG. 12 schematically indicates the pressure-applying state. The method of manufacturing the semiconductor device of the second comparative example, which applies the pressure only to the parts immediately under the bonding parts 41 and 43 of the lead member 4 but does not press the conductive layers 12a and 12b excluding the parts immediately under the bonding parts 41 and 43, could cause a warp of the insulated circuit substrate 1 and thus impede uniform pressure application.

In contrast, the method of manufacturing the semiconductor device according to the first embodiment can apply the pressure, by the pressing jig 8, not only to the parts immediately under the bonding parts 41 and 43 of the lead member 4 but also to the conductive layers 12a and 12b other than the parts immediately under the respective bonding parts 41 and 43. This thus can suppress (correct) a warp of the insulated circuit substrate 1 and enable the uniform pressure application accordingly.

### Second Embodiment

A method of manufacturing a semiconductor device according to a second embodiment of the present disclosure differs from the method of manufacturing the semiconductor device according to the first embodiment illustrated in FIG. 10 in that the pressing jig 8 used for pressing the sintering materials 2x and 2y is divided so as to be separated into a first member 81 and a second member 82, as illustrated in FIG. 13.

The first member 81 and the second member 82 each have a substantially rectangular planar pattern. The first member 81 and the second member 82 are arranged separately from each other. A space between the first member 81 and the second member 82 serves as the opening 8a. The other steps of the method of manufacturing the semiconductor device according to the second embodiment are substantially the same as those of the method of manufacturing the semiconductor device according to the first embodiment, and overlapping explanations are not repeated below.

The method of manufacturing the semiconductor device according to the second embodiment provides the configuration in which the beam part 42 of the lead member 4 overlaps with and is exposed to the opening 8a, so as to prevent the lead member 4 from being deformed and thus avoid an unbonded state between the sintering materials 2x and 2y and the bonding parts 41 and 43. Further, the method of manufacturing the semiconductor device according to the second embodiment can apply the pressure, by the pressing jig 8, not only to the parts immediately under the bonding parts 41 and 43 of the lead member 4 but also to the conductive layers 12a and 12b other than the parts immediately under the respective bonding parts 41 and 43, so as to suppress a warp of the insulated circuit substrate 1 and thus enable the uniform pressure application.

### Third Embodiment

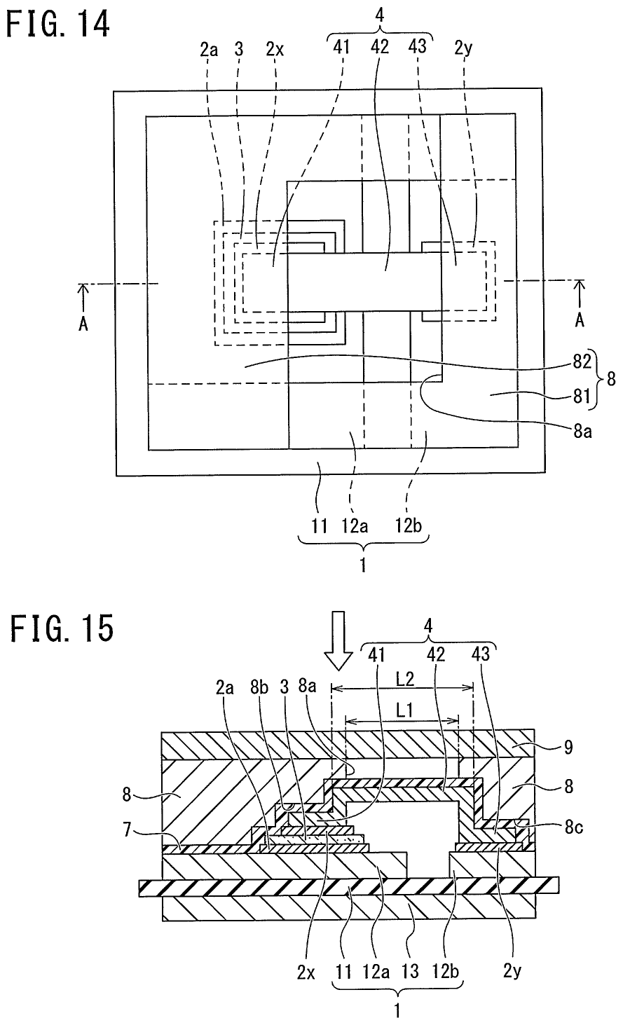

A method of manufacturing a semiconductor device according to a third embodiment of the present disclosure differs from the method of manufacturing the semiconductor device according to the first embodiment illustrated in FIG. 10 in that the pressing jig 8 used for pressing the sintering materials 2x and 2y is divided so as to be separated into the first member 81 and the second member 82, as illustrated in FIG. 14.

The first member 81 and the second member 82 each have an L-shaped planar pattern. The first member 81 and the second member 82 are arranged so that the respective edges overlap with each other. A thickness at the respective edges of the first member 81 and the second member 82 overlapping with each other is thinner than a thickness at the other parts, and a thickness of the part at which the first member 81 and the second member 82 overlap with each other is equal to the thickness of the other parts. A space between the first member 81 and the second member 82 serves as the opening 8a. The other steps of the method of manufacturing the semiconductor device according to the third embodiment are substantially the same as those of the method of manufacturing the semiconductor device according to the first embodiment, and overlapping explanations are not repeated below.

The method of manufacturing the semiconductor device according to the third embodiment provides the configuration in which the beam part 42 of the lead member 4 overlaps with and is exposed to the opening 8a, so as to prevent the lead member 4 from being deformed and thus avoid an unbonded state between the sintering materials 2x and 2y and the bonding parts 41 and 43. Further, the method of manufacturing the semiconductor device according to the third embodiment can apply the pressure, by the pressing jig 8, not only to the parts immediately under the bonding parts 41 and 43 of the lead member 4 but also to the conductive layers 12a and 12b other than the parts immediately under the respective bonding parts 41 and 43, so as to suppress a warp of the insulated circuit substrate 1 and thus enable the uniform pressure application.

### Fourth Embodiment

A method of manufacturing a semiconductor device according to a fourth embodiment of the present disclosure differs from the method of manufacturing the semiconductor device according to the first embodiment illustrated in FIG. 9 in that the opening 8a of the pressing jig 8 used for pressing the sintering materials 2x and 2y has a narrower width. The respective end parts of the opening 8a are located over the bent parts of the beam part 42 of the lead member 4. A length L1 of the opening 8a in the extending direction of the beam part 42 is shorter than a length L2 of the beam part 42. The other steps of the method of manufacturing the semiconductor device according to the fourth embodiment are substantially the same as those of the method of manufacturing the semiconductor device according to the first embodiment, and overlapping explanations are not repeated below.

The method of manufacturing the semiconductor device according to the fourth embodiment provides the configuration in which the beam part 42 of the lead member 4 overlaps with and is exposed to the opening 8a, so as to prevent the lead member 4 from being deformed and thus avoid an unbonded state between the sintering materials 2x and 2y and the bonding parts 41 and 43. Further, the method of manufacturing the semiconductor device according to the fourth embodiment can apply the pressure, by the pressing jig 8, not only to the parts immediately under the bonding parts 41 and 43 of the lead member 4 but also to the conductive layers 12a and 12b other than the parts immediately under the respective bonding parts 41 and 43, so as to suppress a warp of the insulated circuit substrate 1 and thus enable the uniform pressure application.

### Fifth Embodiment

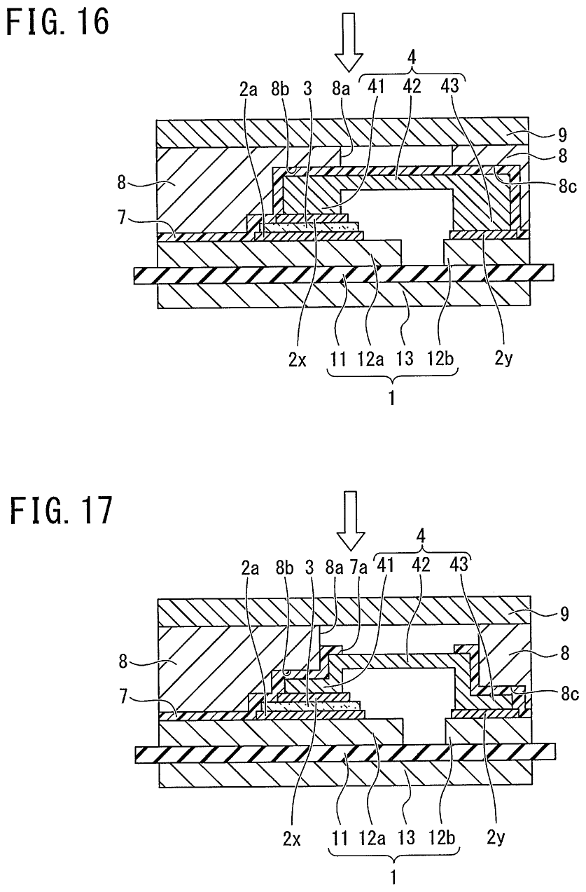

A method of manufacturing a semiconductor device according to a fifth embodiment of the present disclosure differs from the method of manufacturing the semiconductor device according to the first embodiment illustrated in FIG. 9 in the respective shapes of the lead member 4 and the pressing jig 8, as illustrated in FIG. 16. The lead member 4 has a C-like shape in cross section. The lead member 4 includes the bonding parts 41 and 43, and the beam part 42 continuously connected to the respective bonding parts 41 and 43. The beam part 42 does not have parts extending in the vertical direction but only have a part extending in the horizontal direction. The respective stepped parts 8b and 8c of the pressing jig 8 on the bottom surface side have a shape conforming to the shape of the lead member 4. The other steps of the method of manufacturing the semiconductor device according to the fifth embodiment are substantially the same as those of the method of manufacturing the semiconductor device according to the first embodiment, and overlapping explanations are not repeated below.

The method of manufacturing the semiconductor device according to the fifth embodiment provides the configuration in which the beam part 42 of the lead member 4 overlaps with and is exposed to the opening 8a, so as to prevent the lead member 4 from being deformed and thus avoid an unbonded state between the sintering materials 2x and 2y and the bonding parts 41 and 43. Further, the method of manufacturing the semiconductor device according to the fifth embodiment can apply the pressure, by the pressing jig 8, not only to the parts immediately under the bonding parts 41 and 43 of the lead member 4 but also to the conductive layers 12a and 12b other than the parts immediately under the respective bonding parts 41 and 43, so as to suppress a warp of the insulated circuit substrate 1 and thus enable the uniform pressure application.

### Sixth Embodiment

A method of manufacturing a semiconductor device according to a sixth embodiment of the present disclosure differs from the method of manufacturing the semiconductor device according to the first embodiment illustrated in FIG. 9 in that the protection sheet 7 is provided with an opening 7a, as illustrated in FIG. 17. The opening 7a of the protection sheet 7 is provided at a position corresponding to the opening 8a of the pressing jig 8. The other steps of the method of manufacturing the semiconductor device according to the sixth embodiment are substantially the same as those of the method of manufacturing the semiconductor device according to the first embodiment, and overlapping explanations are not repeated below.

The method of manufacturing the semiconductor device according to the sixth embodiment provides the configuration in which the beam part 42 of the lead member 4 overlaps with and is exposed to the opening 8a, so as to prevent the lead member 4 from being deformed and thus avoid an unbonded state between the sintering materials 2x and 2y and the bonding parts 41 and 43. Further, the method of manufacturing the semiconductor device according to the sixth embodiment can apply the pressure, by the pressing jig 8, not only to the parts immediately under the bonding parts 41 and 43 of the lead member 4 but also to the conductive layers 12a and 12b other than the parts immediately under the respective bonding parts 41 and 43, so as to suppress a warp of the insulated circuit substrate 1 and thus enable the uniform pressure application.

### Seventh Embodiment

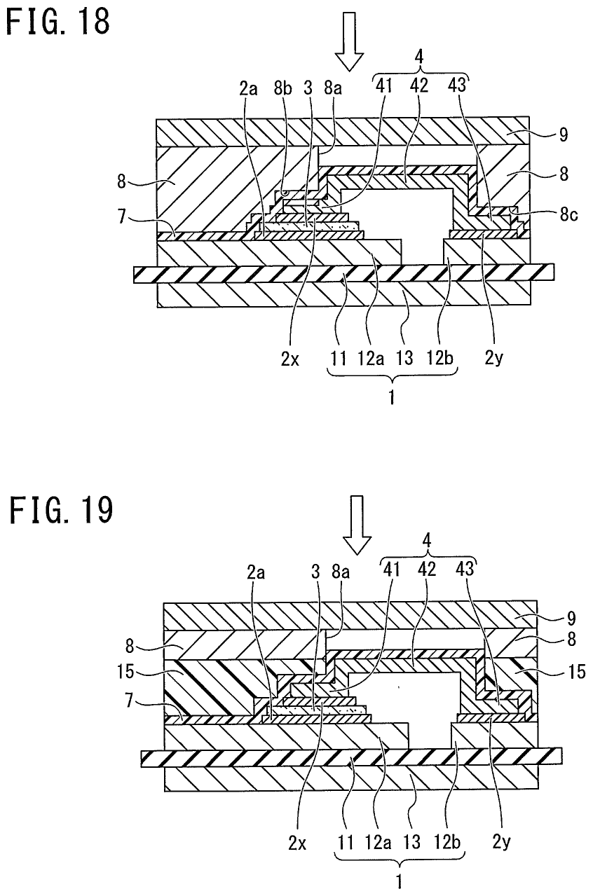

A method of manufacturing a semiconductor device according to a seventh embodiment of the present disclosure differs from the method of manufacturing the semiconductor device according to the first embodiment illustrated in FIG. 9 in that the respective stepped parts 8b and 8c of the pressing jig 8 on the bottom surface side are further provided with finer stepped parts, as illustrated in FIG. 18. The stepped parts 8b and 8c are intended to have shapes so as to be fitted to the steps defined by the bonding layer 2a, the semiconductor chip 3, the sintering materials 2x, and 2y, and the bonding parts 41 and 43, but do not need to have the shapes conforming to those steps one by one. For example, the stepped parts 8b and 8c may each have a single step opposed to the top surface of the respective bonding parts 41 and 43. The other steps of the method of manufacturing the semiconductor device according to the seventh embodiment are substantially the same as those of the method of manufacturing the semiconductor device according to the first embodiment, and overlapping explanations are not repeated below.

The method of manufacturing the semiconductor device according to the seventh embodiment provides the configuration in which the beam part 42 of the lead member 4 overlaps with and is exposed to the opening 8a, so as to prevent the lead member 4 from being deformed and thus avoid an unbonded state between the sintering materials 2x and 2y and the bonding parts 41 and 43. Further, the method of manufacturing the semiconductor device according to the seventh embodiment can apply the pressure, by the pressing jig 8, not only to the parts immediately under the bonding parts 41 and 43 of the lead member 4 but also to the conductive layers 12a and 12b other than the parts immediately under the respective bonding parts 41 and 43, so as to suppress a warp of the insulated circuit substrate 1 and thus enable the uniform pressure application.

### Eighth Embodiment

A method of manufacturing a semiconductor device according to an eighth embodiment of the present disclosure differs from the method of manufacturing the semiconductor device according to the first embodiment illustrated in FIG. 9 in that the pressing jig 8 has a flat bottom surface not provided with any steps, as illustrated in FIG. 19. A buffer member 15 is provided between the bottom surface of the pressing jig 8 and the protection sheet 7. The buffer member 15 can be compressed and deformed by pressure applied by the pressing jig 8. The buffer member 15 is made of a carbon sheet or a PTFE sheet, for example. The other steps of the method of manufacturing the semiconductor device according to the eighth embodiment are substantially the same as those of the method of manufacturing the semiconductor device according to the first embodiment, and overlapping explanations are not repeated below.

The method of manufacturing the semiconductor device according to the eighth embodiment provides the configuration in which the beam part 42 of the lead member 4 overlaps with and is exposed to the opening 8a, so as to prevent the lead member 4 from being deformed and thus avoid an unbonded state between the sintering materials 2x and 2y and the bonding parts 41 and 43. Further, the method of manufacturing the semiconductor device according to the eighth embodiment can apply the pressure, by the pressing jig 8, not only to the parts immediately under the bonding parts 41 and 43 of the lead member 4 but also to the conductive layers 12a and 12b other than the parts immediately under the respective bonding parts 41 and 43, so as to suppress a warp of the insulated circuit substrate 1 and thus enable the uniform pressure application.

### Other Embodiments

As described above, the invention has been described according to the first to eighth embodiments, but it should not be understood that the description and drawings implementing a portion of this disclosure limit the invention. Various alternative embodiments of the present disclosure, examples, and operational techniques will be apparent to those skilled in the art from this disclosure.

For example, while the respective semiconductor devices according to the first to eighth embodiments have been illustrated above with the case in which the pressing jig 8 is provided with the single opening 8a, the respective embodiments, when including a plurality of semiconductor chips and a plurality of lead members connected to the respective semiconductor chips, may have a structure in which the pressing jig 8 is provided with a plurality of openings overlapping with the respective beam parts of the lead members. Alternatively, the pressing jig 8 may be provided with a single opening collectively overlapping with the respective beam parts of the lead members.

Further, the respective semiconductor devices according to the first to eighth embodiments have been illustrated above with the case of sintering the sintering material for bonding the insulated circuit substrate 1 and the semiconductor chip 3 together to form the bonding layer 2a first, and then sintering the sintering materials 2x and 2y to form the bonding layer 2b and 2c. Alternatively, the respective embodiments may have a configuration in which the sintering material for bonding the insulated circuit substrate 1 and the semiconductor chip 3 together before being sintered is prepared and arranged first, and is then sintered so that the bonding layer 2a is formed simultaneously with the timing at which the sintering materials 2x and 2y are sintered by being pressed and heated so that the bonding layers 2b and 2c are formed.

In addition, the respective configurations disclosed in the first to eighth embodiments can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

1. A semiconductor device comprising:
an insulated circuit substrate including an insulating plate and a conductive layer provided on the insulating plate;
a semiconductor chip provided on the conductive layer;
a bonding layer including sintering material provided on the semiconductor chip; and
a lead member including a bonding part provided on the bonding layer and a beam part continuously connected to the bonding part,
wherein the bonding layer includes a middle region located immediately under the bonding part, and a circumferential region located on an outer side of the middle region, and
the circumferential region has lower sintered density at a part located immediately under the lead member than at a part other than the part located immediately under the lead member.

2. A method of manufacturing a semiconductor device, comprising:
preparing a lead member including a bonding part and a beam part continuously connected to the bonding part;
preparing a pressing jig provided with an opening;
placing the bonding part, with sintering material interposed, on a semiconductor chip provided on a conductive layer of an insulated circuit substrate, the insulated circuit substrate including an insulating plate and the conductive layer provided on the insulating plate;
placing the pressing jig on the bonding part, the sintering material, the semiconductor chip, and the conductive layer so that the opening overlaps with the beam part; and
applying pressure and heat to the bonding part, the sintering material, the semiconductor chip, and the conductive layer by the pressing jig.

3. The method of manufacturing the semiconductor device of claim 2, wherein the pressing jig is provided with a stepped part on a bottom surface side.

4. The method of manufacturing the semiconductor device of claim 2, wherein the opening has a greater size than the beam part.

5. The method of manufacturing the semiconductor device of claim 2, wherein the opening has a greater length than the beam part in a longitudinal direction of the beam part.

6. The method of manufacturing the semiconductor device of claim 2, wherein the opening has a smaller length than the beam part in a longitudinal direction of the beam part.

7. The method of manufacturing the semiconductor device of claim 2, wherein the applying pressure by the pressing jig presses the bonding part, the sintering material, the semiconductor chip, and the conductive layer by the pressing jig with a protection sheet interposed.

8. The method of manufacturing the semiconductor device of claim 7, wherein the protection sheet is provided with an opening at a position corresponding to the opening.

9. The method of manufacturing the semiconductor device of claim 2, wherein the applying pressure by the pressing jig places a pressing plate on a top surface side of the pressing jig so as to press the bonding part, the sintering material, the semiconductor chip, and the conductive layer by the pressing plate and the pressing jig.
